(19) United States
(12) Patent Application Publication
(10) Pub. No.: US 2004/0150956 A1
(43) Pub. Date: Aug. 5, 2004

(54) Pin fin heat sink for power electronic applications

(76) Inventor: Robert Conte, North Babylon, NY (US)

Correspondence Address: Larry Liberchuk, Esq., P.O. Box 385, Edgewater, NJ, 07020, US

(21) Appl. No.: 10/762,890

(22) Filed: Jan. 22, 2004

Related U.S. Application Data
(60) Provisional application No. 60/442,432, filed on Jan. 24, 2003.

(51) Int. Cl. H05K 7/20

(52) U.S. Cl. 361/709

(57) ABSTRACT

A heat sink comprises pins, located in a holding base plate, that are positioned so that the end of each pin is exposed and attached by a thermally conductive material to a heat generating source, such as an internal electronic insulator assembly or a semiconductor die. The pins have various diameters and shapes, such as circular, square, diamond, helical, elliptical, triangular and rectangular that can be made from any thermally conductive material, such as metals, ceramics, organic and inorganic compounds. The pins are located inside a holding base plate that can comprise a medium that will support the structure, such as metals, plastics, ceramics, polymeric, organic and inorganic compounds. The pins are arranged in a geometric pattern of any design shape, repetition of such patterns and concentration of such patterns. The ends of the pins can be straight flat cut or of nail head design.

### CROSS-REFERENCE TO RELATED APPLICATIONS

This application claims the benefit of U.S. Provisional Application No. 60/442,432, filed Jan. 24, 2003.

### BACKGROUND OF THE INVENTION

The present invention is related to a pin fin heat sink. More specifically, the present invention is related to a device for dissipating heat from one surface, such as a power electronic device, directly to the cooling medium used for regulating the device temperature.

Heat sinks expel heat from one heating surface to another surface that is in contact with a cooling source or medium, such as air, liquid, etc. The cooling rate depends on the amount of surface area of the material that the heat sink is manufactured from and the medium used to cool the heat sink. To increase the surface area without increasing the component size, surfaces that extend into the cooling medium are applied to the outside of the component. Power electronics designs use various shapes, geometric designs and materials of pin fins to achieve the desired results. Internally, power electronics assemblies that use a high power FET, diode, IGBT, and/or other power semiconductor rely on a ceramic based or other substrate material for electrical insulation. Such materials are generally thermally conductive to provide a heat path to the base plate through soldering or a brazed operation. The base plate then provides a heat path to the pin fin heat sink via a thermally conductive medium, such as grease, tape, etc. Solid type pin fin heat sinks are manufactured from either a solid block of metal by a machining or molding process or having pins inserted halfway into a solid block of metal.

Many devices have been developed over the years to enhance this method of heat removal from the base plates of high power devices to the pin fins. Spring contact systems, wedge locks systems and the use of clips, screws and soldering the pin fins to the base plate directly have been employed, among other things. The use of these devices has caused an increase in weight of the final assembly. While these devices provide an adequate means of removing heat, the full potential of getting the coolant medium closer to the heat generating source have not been realized.

Drawbacks of conventional pin fin heat sinks are as follows:

Increased thermal resistance from the bottom of the power electronic device to the pin fin heat sink itself due to an interface layer applied to hold and provide contact for the pin fin heat sink.

Distance from the pin fin heat sink to the actual heat-generating substrate inside the power electronic package is too large in the ever increasing power density of today's power electronic designs.

Increased overall system weight by adding additional mass to the power electronic device.

Mechanical hardware is needed to attach current pin fin heat sinks to the back side of the base plates, increasing manufacturing cost.

A need therefore exists for a device that addresses the above concerns and solves this long-felt need for a pin fin heat sink.

### SUMMARY OF THE INVENTION

It is an object of the present invention to provide a heat sink assembly for dissipating heat from a heat generating source to a cooling medium in power electronics applications.

The above and other objects are achieved by a heat sink assembly used in power electronics applications for transferring heat from a heat generating source to a cooling medium. According to the present invention, the heat sink assembly comprises a base plate and a plurality of thermally conductive pins located in the base plate. The pins transfer heat from the heat generating source to the cooling medium, extending substantially perpendicular to the base plate. A first end of each pin is in contact with the heat generating source.

The pin fin heat sink of the present invention minimizes the thermal resistance between the heat generating source and the cooling medium used to control temperature, such as air, liquid, etc. Among other things, one of the advantages of the present invention is the use of low cost materials. The pin fin heat sink comprises a plurality of pins protruding through and perpendicular to a flat base plate material. Various characteristics and features of the pin fin heat sink are independent of the base plate material that holds the pin fins in place. Applications of the pin fin heat sink in accordance with the present invention are in avionics, land, and sea-based systems.

Among other things, keeping power electronics cooler increases the reliability of power electronic components. The pin fin heat sink of the present invention can be used as a replacement for a conventional pin fin heat sink in electronics.

### BRIEF DESCRIPTION OF THE DRAWINGS

The present invention is illustrated in the figures of the accompanying drawings which are meant to be exemplary and not limiting, and in which like reference characters are intended to refer to like or corresponding parts:

FIG. 1 shows the top view of one embodiment of the present invention with pins installed;

FIG. 2A is a cutaway view of FIG. 1 along the line 1-1;

FIG. 2B is the detailed section of FIG. 2A;

FIG. 3 is the bottom view of the heat sinks as shown in FIG. 1;

FIG. 4A shows the electrical insulator with the pin fins attached;

FIG. 4B is the detailed section of FIG. 4A;

FIGS. 5A-5F show a sectional view of FIG. 3 with various pin shapes;

FIG. 5G shows a cutaway view of a pin design;

FIG. 5H shows a cutaway view of another pin design;

FIG. 6 shows one embodiment of the present invention with a pin layout design;

FIG. 7 shows a pin fin heat sink with a coolant channel in accordance with one embodiment of the present invention; and

FIG. 8 shows a dual pin fin heat sink with a coolant channel in accordance with another embodiment of the present invention.

### DETAILED DESCRIPTION OF PREFERRED EMBODIMENTS

The present invention comprises a pin fin heat sink where the pins, in a holding base plate, are positioned so that the end of the pin itself will be exposed and attached to the internal electronic insulator assembly or semiconductor component through various materials, such as metals, plastics, polymers, organic and inorganic compounds. The pins in the present invention have various diameters and shapes, such as circular or tubular, square, diamond, helical, elliptical, triangular and rectangular that can be made from any thermally conductive material, such as metals, ceramics, organic and inorganic compounds. The pins are located inside a holding base plate that can comprise a medium that will support the structure, such as metals, plastics, ceramics, polymeric, organic and inorganic compounds. The pins are arranged in a geometric pattern of any design shape, repetition of such patterns and concentration of such patterns. The ends of the pins can be straight flat cut or of nail head design.

Since the pins in the pin fin heat sink are independent of each other, the contact cross sectional area is smaller than the solid type of pin fin attachment. This smaller cross sectional area reduces the thermal mismatch between the pin and internal electronic insulator assembly and semiconductor device. The smaller cross sectional area of each pin head makes the direct attachment to the heat generating source with higher thermally conductive materials, such as solders, thereby increasing the cooling efficiency. Pressure contact can also be employed where'device slippage is required. The pin fin heat sink is made with low cost components.

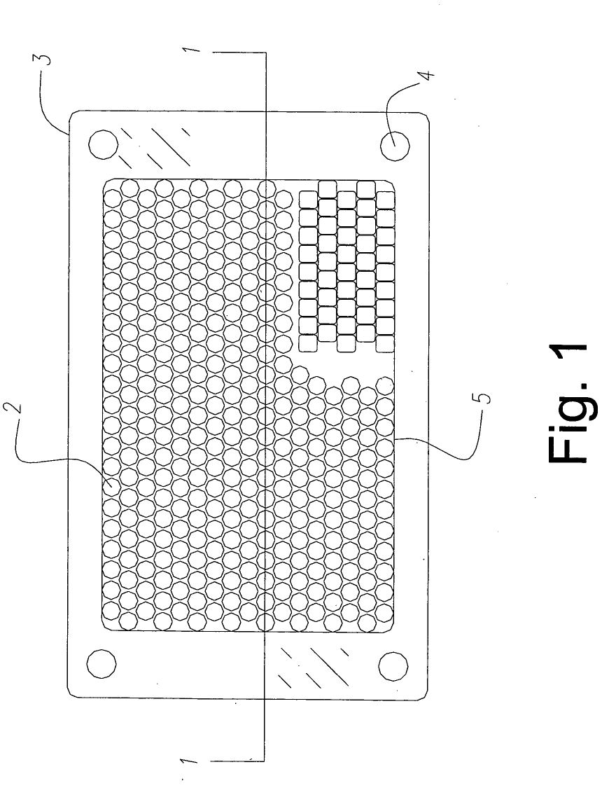

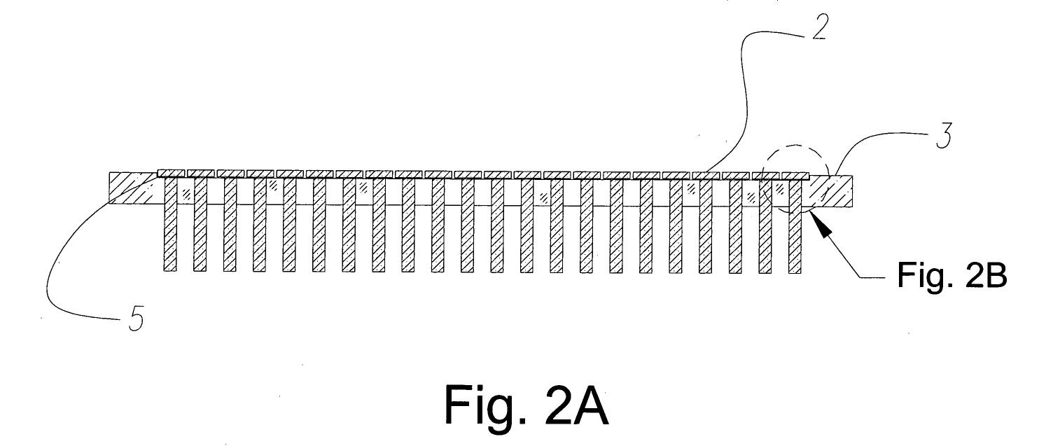

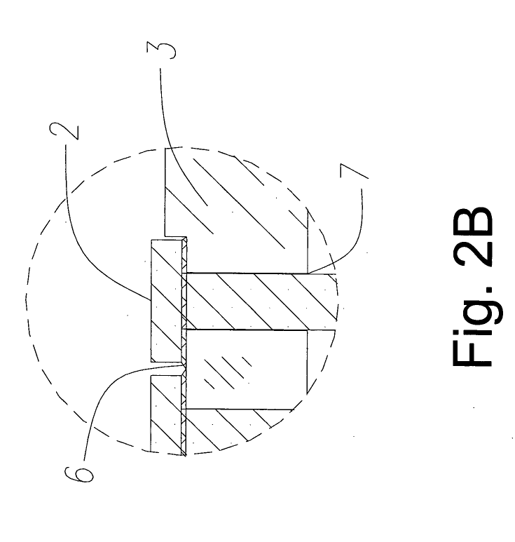

FIG. 1 shows base plate 3, so-called support structure, for holding pins 2 in place. Base plate 3 can be made from any medium that will support such structure as metals, plastics, ceramics, polymeric, organic and inorganic compounds. Top portion of pins 2 is shown in this particular embodiment to be round, with a nail head at one end—see also FIG. 2A. The nail head can also be square to facilitate an increased contact area with the electronic components in nonmetallic attachment application. The pattern and concentration of the pin pattern is determined by the layout of the high temperature electronic components. In FIG. 1 the representative pattern is a staggered row design.

Further referring to FIG. 1, a pocket 5 is an indented portion in the base plate 3 that may be provided therein—see also FIG. 2A. Pocket 5 may be omitted if the material of base plate 3 is sufficiently thin in the section where the pins are inserted. Mounting holes 4 are made in base plate 3 in order to secure it to a heat exchange assembly. It will be appreciated that mounting holes 4 do not have to be round in shape or located at the edge of base plate 3.

FIG. 2A is a cutaway of base plate 3 and pin fin assembly of the present invention. Shown in FIG. 2A are base plate 3 and the top portion of pins 2 that contacts the electronic assembly or a semiconductor die. The pins are shown perpendicular to the base plate for maximum thermal contact. If needed, pocket 5 in base plate 3 may contain the pins. Top portion of pins 2 is slightly above a non-indented portion of base plate 3 in order to have the top portion of the pins touch the heat generating component.

FIG. 2B is a detailed view of FIG. 2A, which shows base plate 3 and pins 2 with top portion. In this particular embodiment holding medium 6 holds the pins 2 in place. The holding medium 6 can be solder or any other adhesive, for example, as known to those skilled in the art. If the base plate 3 is manufactured in a molding process, the holding medium 6 may be omitted. Clearance holes 7 are provided in base plate 3 if the materials used are to be machined in order to insert the pins 2 into base plate 3.

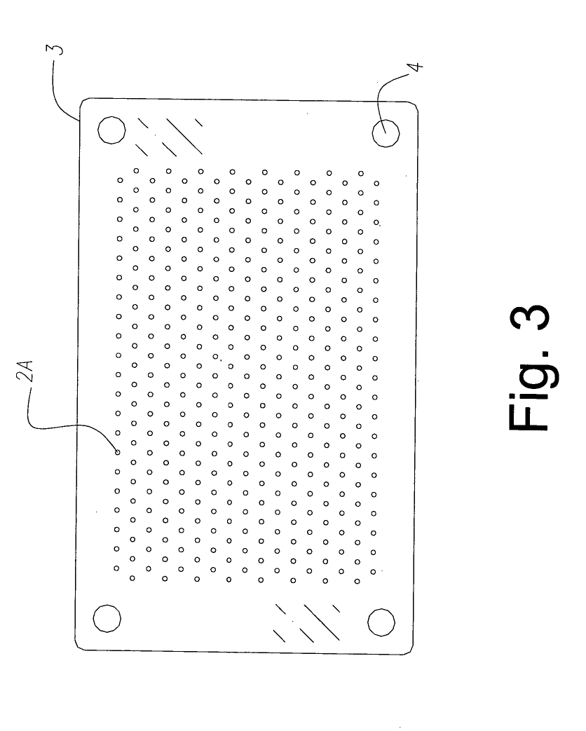

FIG. 3 is the bottom view of FIG. 1, showing the pins 2 on the other side of the base plate 3. Bottom portion 2A of pins 2 is shown in FIG. 3.

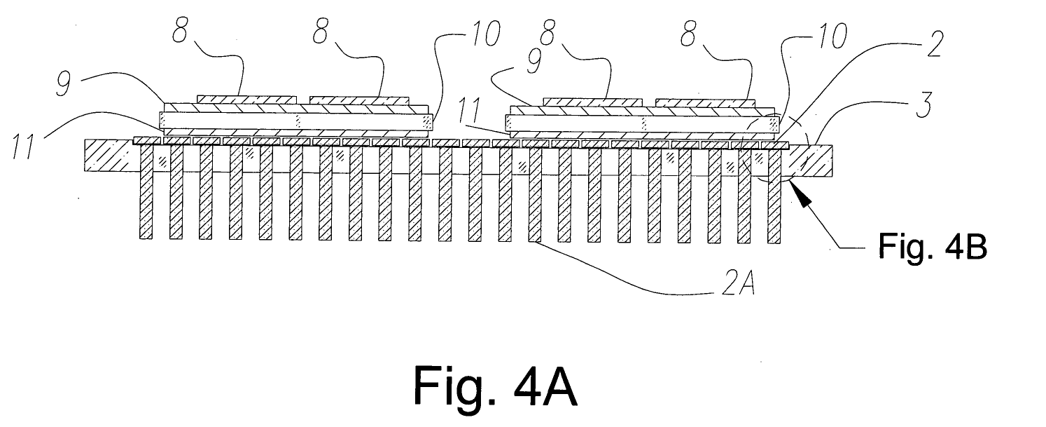

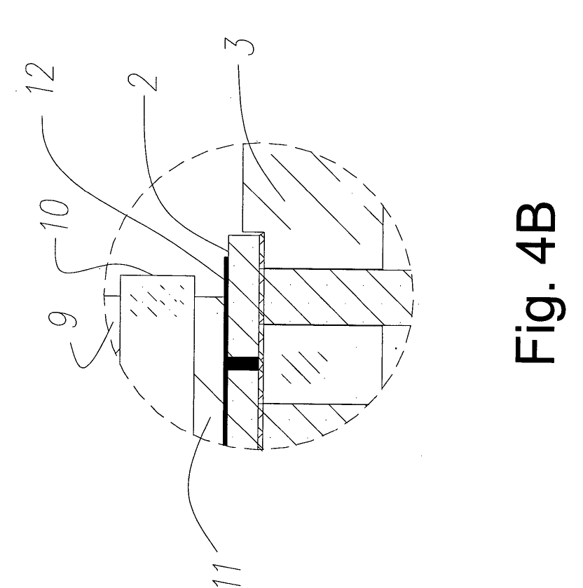

FIG. 4A provides a detailed view of FIG. 2A, as well as additional features of the present invention, such as an electronic insulator assembly, designated with reference numerals 8, 9, 10, 11 attached to the top portion of pins 2. Namely, semiconductor die 8, so-called semiconductor component, is attached to the top layer 9 of insulator 10. The top layer 9 may be attached or joined to the insulator 10 by any process that will support electrical conductivity for semiconductor die 8. It will be appreciated that in certain applications, top layer 9 may not be present. It will be further appreciated that in certain applications there is no need for electrical conductivity between semiconductor die 8 and top layer 9. Bottom layer 11 of the insulator 10 may be attached or joined to it by any process that supports electrical conductivity or used to support the attachment process to pins 2. FIG. 4A shows two electrical components, but the present invention can also support either a single large electronic component or a plurality of electronic components.

FIG. 4B is a detailed view of FIG. 4A. The internal electronic insulator assembly, which is comprised of elements 8, 9, 10 and 11, as described above and shown in FIG. 4A, is attached to pins 2 by a thermally conductive adhesive material, such as metals, plastics, polymeric, organic and inorganic compounds. Alternatively, in certain applications semiconductor die 8 alone, i.e., without the top and bottom layers 9, 11, may be attached to pins 2 by a thermally conductive adhesive material, such as metals, plastics, polymeric, organic and inorganic compounds.

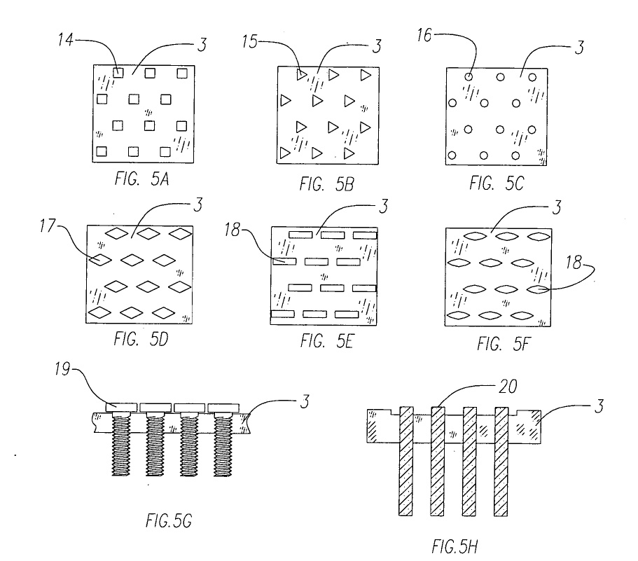

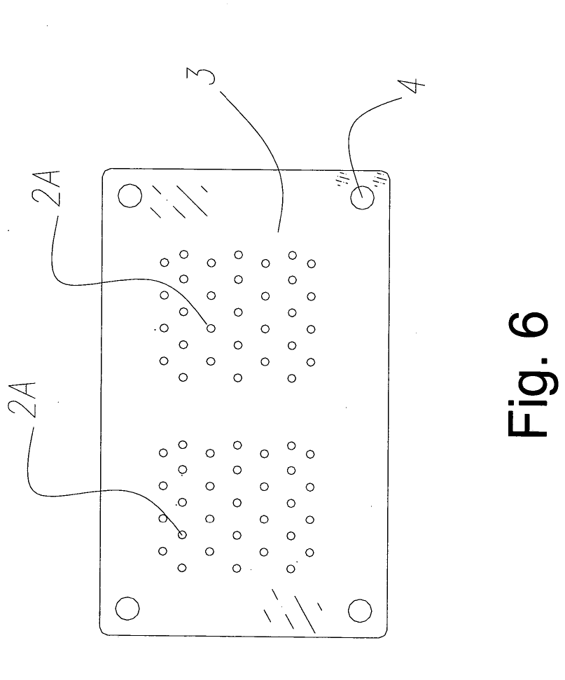

FIGS. 5A-5F show a sectional view of FIG. 3 with different pin shapes that can be used with the pin fin heat sink of the present invention. FIG. 5A shows exposed portion 14 of pins 2 shaped as a square. Exposed portion 14 is that portion of pins 2 that is exposed to any cooling medium. FIG. 5B shows exposed portion 15 of pins 2 shaped as a triangle. FIG. 5C shows exposed portion 16 of pins 2 shaped as a circle. FIG. 5D shows exposed portion 17 of pins 2 shaped as a diamond. FIG. 5E shows exposed portion 18 of pins 2 shaped as a rectangle. FIG. 5F shows exposed portion 18 of pins 2 shaped as an ellipse.

FIG. 5G is a side view showing a helical pin shape 19. FIG. 5H is a side view showing a straight pin shape 20.

FIG. 6 shows a pin layout design. The pattern shape is concentrated into two groups, but there can be various pattern shapes and groupings depending on the power dissipation needed to keep the electronics cool. Sectional cooling of a hot component or a section of a larger component attached to the other side—see FIG. 4A for reference—can be designed in the present invention.

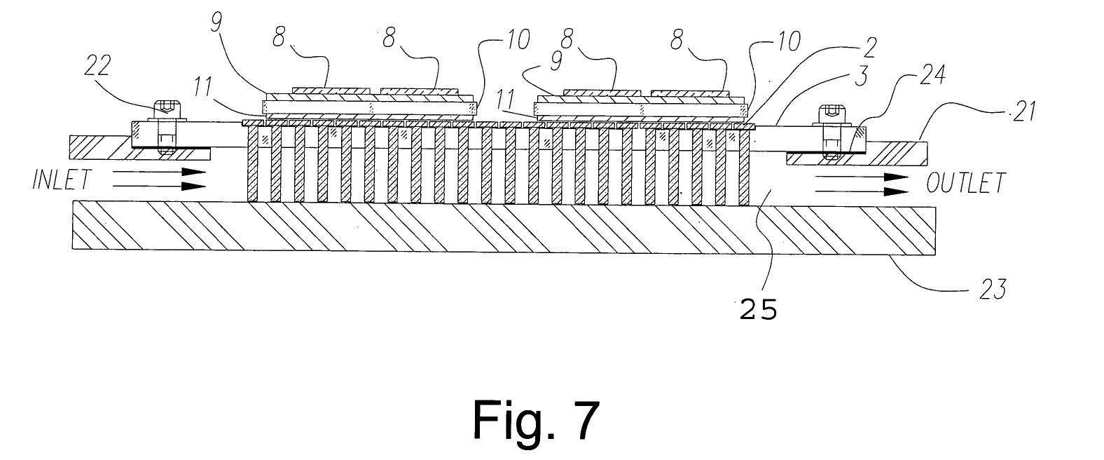

FIG. 7 shows coolant channel 25 in accordance with the present invention. Components as shown in FIG. 4A are mounted to a heat exchange assembly, comprised of first mounting portion 21 and second mounting portion 23, forming coolant channel 25 for a coolant medium to flow therebetween. FIG. 7 shows first mounting portion 21 to which elements, as illustrated in FIG. 4A, are mounted using mounting hardware 22 and gasket material 24. In one embodiment of the present invention the pin lengths slightly touch the second mounting portion 23 while providing a proper seal to prevent leaks in a liquid cooled application. It is understood, however, that in other embodiments of the present invention pins 2 may be slightly shorted than the distance between first mounting portion 21 and second mounting portion 23, i.e., the width of coolant channel 25. The expansion rate of pins 2 in the longitudinal direction is calculated so as not to exceed the width of coolant channel 25 during the expansion of pins 2 when hot. However, care must be taken not to cut pins 2 too short, since this will cause coolant to substantially bypass pins 2 without providing any cooling effect. It is understood that gasket material 24 may not be needed in certain types of heat exchange operations. The pin fin heat sink of the present invention is mounted in such a way as to maximize the heat transfer between the electronic assembly and the coolant medium.

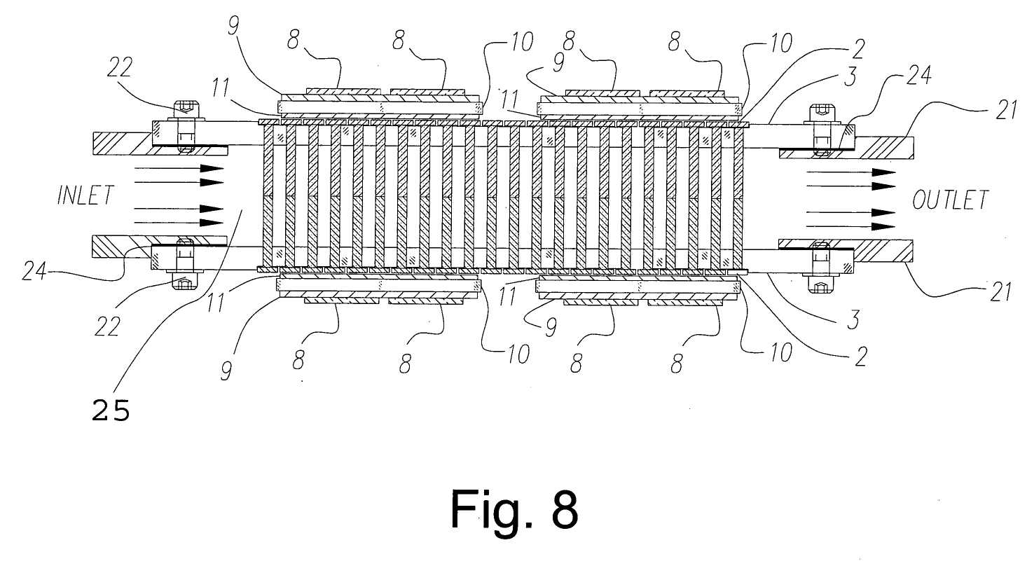

FIG. 8 shows the details from FIG. 7 in a dual pin fin heat sink channel. This embodiment is similar to FIG. 7 in that the components shown in FIG. 4A are mounted to a heat exchange assembly, which in this embodiment is comprised of a pair of first mounting portion 21 creating coolant channel 25 therebetween, using mounting hardware 22 and gasket material 24. FIG. 8, however, shows two pin fin heat sinks in a “back to back” configuration. In some electronic systems, a mating pair or several pairs of electronic modules share the same heat exchange assembly. Care is taken to account for the expansion of pins 2 in the longitudinal direction so as not to touch the other side of pins 2 while hot. However, cutting pins 2 too short will cause coolant to bypass them. As described above, gasket material 24 may not be needed in certain types of heat exchange operations. The pin fin heat sink is mounted in such a way as to maximize the heat transfer between the heat generating source and the coolant medium. Pins 2 in one module in this “back to back” configuration can be offset from the pin 2 of the other corresponding module in order to provide a wave type flow passage for the cooling medium.

While the invention has been described and illustrated in connection with preferred embodiments, many variations and modifications as will be evident to those skilled in this art may be made without departing from the spirit and scope of the invention, and the invention is thus not to be limited to the precise details of methodology or construction set forth above as such variations and modification are intended to be included within the scope of the invention.

What is claimed is:

1. A heat sink assembly used in power electronics applications for transferring heat from a heat generating source to a cooling medium, comprising:
a first base plate; and
a first plurality of thermally conductive pins located in said first base plate for transferring heat from said heat generating source to said cooling medium, said first plurality of pins extending substantially perpendicular to said first base plate, a first end of each pin of said first plurality of pins being in contact with said heat generating source.

2. The heat sink assembly according to claim 1, wherein said heat generating source is comprised of an electronic insulator assembly having a semiconductor die and an insulator that is sandwiched between a top layer and a bottom layer, said semiconductor die positioned on said first layer, said second layer being in contact with said first plurality of pins.

3. The heat sink assembly according to claim 1, wherein said heat generating source is comprised of a semiconductor die being in contact with said first plurality of pins.

4. The heat sink assembly according to claim 1, wherein said first end of each pin of said first plurality of pins is slightly above a plane of said first base plate in order to contact said heat generating source.

5. The heat sink assembly according to claim 1, wherein said first base plate comprises a non-indented portion and an indented portion for holding said first plurality of pins, said first end of each pin of said first plurality of pins being slightly above a non-indented portion of said first base plate in order to contact said heat generating source.

6. The heat sink assembly according to claim 1, wherein said first plurality of pins is attached to said first base plate by an adhesive.

7. The heat sink assembly according to claim 1, wherein said heat generating source is attached to said first plurality of pins by a thermally conductive adhesive.

8. The heat sink assembly according to claim 1, wherein said first plurality of pins have a geometric shape selected from a square, a triangle, a circle, a diamond, a rectangle, and an ellipse.

9. The heat sink assembly according to claim 1, wherein said first plurality of pins is arranged in a predetermined layout pattern.

10. The heat sink assembly according to claim 1, further comprising a heat exchange assembly having a top mounting portion, a bottom mounting portion, and a coolant channel formed therebetween, such that said cooling medium for absorbing heat is located in said coolant channel.

11. The heat sink assembly according to claim 10, wherein a second end of each pin of said first plurality of pins is positioned in said coolant channel for transferring heat from said heat generating source to said cooling medium.

12. The heat sink assembly according to claim 11, further comprising mounting hardware for attaching said first base plate to said top mounting portion.

13. The heat sink assembly according to claim 12, further comprising a gasket material for preventing said cooling medium to escape from said coolant channel.

14. The heat sink assembly according to claim 13, wherein a surface on said second end of each pin of said first plurality of pins, substantially perpendicular to a longitudinal direction of said first plurality of pins, slightly contacts said bottom mounting portion during the expansion of said first plurality of pins due to a heat transfer process.

15. The heat sink assembly according to claim 10, further comprising a second base plate and a second plurality of thermally conductive pins located in said second base plate for transferring heat from another heat generating source to said cooling medium, said second plurality of pins extending substantially perpendicular to said second base plate, a first end of each of said second plurality of pins being in contact with said another generating source, said second base plate located substantially parallel and opposite said first base plate, such that said first and second plurality of pins are mirror images of each other being positioned in said coolant channel.

16. The heat sink assembly according to claim 15, wherein a pin in said first plurality of pins is offset from a corresponding pin in said second plurality of pins, such that a wave type of passage is created for said cooling medium.
